(19) United States
(12) Patent Application Publication
(10) Pub. No.: US 2015/0160313 A1
(43) Pub. Date: Jun. 11, 2015

(54) SYSTEM AND METHOD FOR DIRECT RADIO FREQUENCY PHASE CONTROL IN MAGNETIC RESONANCE IMAGING

(71) Applicant: Andrzej Jesmanowicz, Brookfield, WI (US)

(72) Inventor: Andrzej Jesmanowicz, Brookfield, WI (US)

(21) Appl. No.: 14/394,874

(22) PCT Filed: Apr. 16, 2013
(86) PCT No.: PCT/US13/36792

§ 371 Date: Oct. 16, 2014

Related U.S. Application Data
(60) Provisional application No. 61/624,570, filed on Apr. 16, 2012.

(51) Int. Cl. G01R 33/36

(52) U.S. Cl. CPC G01R 33/3607; G01R 33/3621

(57) ABSTRACT

Described here are systems and methods for improved magnetic resonance imaging (“MRI”} using a radio frequency (“RF”} system that establishes a Larmor frequency using a clock signal generated by the RF system to provide phase coherency and improved spectral quality among the RF pulses generated by the RF system. With this system, the conventionally relied-upon reference signal is no longer needed to maintain phase coherency. Instead, the system clock of the RF system is used to create the Larmor frequency used for pulse formation in the RF transmitter and for signal demodulation in the RF receiver.

### CROSS-REFERENCE TO RELATED APPLICATIONS

This application claims the benefit of U.S. Provisional Patent Application Ser. No. 61/624,570, filed on Apr. 16, 2012, and entitled “Method for Consistent Phase Contrast Volumetric Magnetic Resonance Imaging From a Set of Two-Dimensional Slices Without Using A Reference Frequency.”

### STATEMENT REGARDING FEDERALLY SPONSORED RESEARCH

This invention was made with government support under R01 EB007827 awarded by the National Institutes of Health. The government has certain rights in the invention.

### BACKGROUND OF THE INVENTION

The field of the invention is systems and methods for nuclear magnetic resonance (“NMR”). More particularly, the invention relates to systems and methods for direct radio frequency (“RF”) phase control in magnetic resonance imaging (“MRI”) using digital waveform playback at the Larmor frequency to remove the requirement for a reference signal.

In MRI, the magnetic resonance signals produced by a subject being imaged in response to excitation by RF excitation pulses is picked up by a receiver coil. Because the received signal is at or around the Larmor frequency, and because hardware-based receiver systems cannot provide adequate sampling at such high frequencies, this high frequency signal is down-converted in a two-step process by a down converter that first mixes the imaging signal with the carrier signal and then mixes the resulting difference signal with a reference signal. In this regard, these hardware systems typically down convert the received analog signals to an intermediate frequency that is less than the Larmor frequency and then mix it with an analog reference signal.

Only after this conversion and mixing is the signal finally digitized by an analog-to-digital converter (“ADC”) that samples and digitizes the down-converted/mixed analog signal. Once digitized, the signal is applied to a digital detector and signal processor that produces in-phase values and quadrature values corresponding to the received signal. Therefore, only after a variety of significant analog processing steps are the analog signals finally digitized and processed to reconstruct the resulting image.

To carry out these mixing and digitizing processes, hardware systems are employed that are specifically tailored to the particular MRI system with which the mixing and digitizing hardware is to be associated. For example, once the constraints of a particular MRI system are identified (i.e., 1.5 Tesla or 3 Tesla and capable of only echo-planar imaging processes or capable of other fast-spin-echo techniques, such as gradient- and spin-echo processes), hardware that is specifically designed to prepare (i.e., synchronize and digitize) the imaging data received under those constraints is coupled therewith. That is, the hardware is specifically designed and tailored to perform down-conversion, mixing, and analog-to-digital conversion under the specific constraints and parameters (i.e., sampling frequency and Larmor frequency) necessary for a given MRI system.

While these hardware-based systems yield suitable results, they are extremely rigid since they are specifically designed and tailored for a particular MRI system. Thus, as various hardware designs and components attain higher bandwidth and dynamic range, these MRI systems cannot harness these capabilities to yield higher quality images without hardware-level redesigns and reconfigurations of the receiver system.

To preserve the phase information contained in the received magnetic resonance signals, a common signal is used to generate a carrier signal and a reference signal in a frequency synthesizer. The carrier and reference signals are both used in the up-conversion and down-conversion processes in the MRI system's RF hardware. Phase consistency is thus maintained and phase changes in the detected magnetic resonance signals accurately indicate phase changes produced by the excited spins. The reference signal is produced from a common master clock signal.

In practice this type of frequency synthesizer cannot operate over a very wide range of frequencies, because the comparator will have a limited bandwidth and may suffer from aliasing problems. This would lead to false locking situations, or an inability to lock at all. In addition, it is hard to make a high frequency oscillator that operates over a very wide range. This is yet another reason why hardware-based RF systems are designed for use with specific MRI systems.

It would therefore be desirable to have a system and method for facilitating the adaptability necessary to accommodate changing component constraints in MRI. Furthermore, it would be desirable to provide and RF system for MRI that was capable of achieving RF phase stability without the need for a reference signal that can limit the scalability of the RF hardware.

### SUMMARY OF THE INVENTION

The present invention overcomes the aforementioned drawbacks by providing a system and method for direct radio frequency (“RF”) phase control in magnetic resonance imaging (“MRI”) using digital waveform playback at the Larmor frequency.

It is an aspect of the invention to provide an RF system for an MRI system that includes a clock configured to generate a clock signal, and RF transmitter in communication with the clock, and an RF receiver in communication with the RF transmitter. The RF transmitter includes an oscillator capable of receiving the clock signal from the clock and capable of generating a Larmor frequency signal in response thereto. The RF transmitter also includes a digital-to-analog convertor capable of receiving the Larmor frequency signal from the oscillator and using the Larmor frequency signal to generate a complex waveform that defines an RF pulse. The RF receiver includes an analog-to-digital converter capable of receiving a magnetic resonance signal produced by a subject placed in the MRI system and configured to produce a complex digital signal therefrom. The RF receiver also includes a demodulator connected to receive the Larmor Frequency signal from the RF transmitter and the complex digital signal from the analog-to-digital convertor, the demodulator being capable of demodulating the complex digital signal using the Larmor frequency.

It is another aspect of the invention to provide a waveform generator capable of generating complex waveforms that define RF pulses for use in an MRI system that includes a digital-to-analog convertor assembly in communication with and controlled by a controller. The digital-to-analog convertor assembly includes an input capable of receiving digital signals that define a complex waveform to be generated, an oscillator capable of generating a Larmor frequency in response to a clock signal received from a clock, a mixer in communication with the input and the oscillator, the mixer configured to generate a mixed signal by mixing the digital signals and the Larmor frequency, a digital-to-analog convertor capable of converting the mixed signal into a complex waveform, and an output capable of outputting the complex waveform to an RF transmitter.

The foregoing and other aspects and advantages of the invention will appear from the following description. In the description, reference is made to the accompanying drawings which form a part hereof, and in which there is shown by way of illustration a preferred embodiment of the invention. Such embodiment does not necessarily represent the full scope of the invention, however, and reference is made therefore to the claims and herein for interpreting the scope of the invention.

### BRIEF DESCRIPTION OF THE DRAWINGS

FIG. 1 is a block diagram of an example of a magnetic resonance imaging (“MRI”) system;

FIG. 2 is a block diagram of a radio frequency (“RF”) system in accordance with the present invention and that forms a part of the MRI system of FIG. 1; and

FIG. 3 is a block diagram of a digital-to-analog convertor that forms a part of a waveform generator used in the RF system of FIG. 2.

### DETAILED DESCRIPTION OF THE INVENTION

Described here are systems and methods for improved magnetic resonance imaging (“MRI”) using a radio frequency (“RF”) system that includes an RF transmitter, receiver, or both, that are configured to establish a Larmor frequency using a clock signal generated by the RF system, rather than the traditional approach that requires the mixing of analog signals.

The present invention provides a single RF system that can be implemented on any number of different MRI systems (e.g., MRI systems covering a wide range of different magnetic field strengths). Using this highly flexible RF system, the overall cost of the MRI system can be reduced.

The wide-ranging applicability of RF systems that implement the present invention is achieved because the conventionally relied-upon reference signal is no longer needed to maintain phase coherency. Instead, the system clock of the RF system is used to create the Larmor frequency used for pulse formation in the RF transmitter and for signal demodulation in the RF receiver.

The spectral purity of RF pulses made in this way is significantly improved relative to the quality of RF pulses made by standard modulators. Using the present invention, there is no need to mix reference signal waveforms with the received magnetic resonance signals to obtain inter-k-space coherency for different repetitions.

Phase coherence of all k_{y}-space lines is required to obtain an undistorted image that is created by Fourier transformation. Any phase deviation, even of a single k_{y}-space line, creates smearing in the image along the phase-encoding direction. Existing MRI systems obtain this coherency by mixing a reference signal with the with magnetic resonance signals before acquisition. Because the same low frequency digital synthesizer and up-converting free-running clock are used to obtain an RF excitation pulse and the reference signal, coherency between them is assured. This approach has been adequate to obtain consistent k-space coverage in spite of the lack of coherency between RF pulses and the MRI sequence itself, but RF systems using this approach must be specifically designed for each MRI system and are not scalable to different magnetic field strengths or to allow for developments in other hardware components.

The present invention thus yields several benefits, including improved phase stability, improved spectral quality, and improved reliability. High spectral quality and stability of RF pulses is possible with an RF system that employs a digital-to-analog convertor (“DAC”) in the RF signal processing stage that uses a high clock rate. By way of example, the system may use a clock rate of about 500 MHz to about 1.5 GHz; however, it will be appreciated that higher clock rates can be achieved as well. The DAC is preferably designed to include short connections within the chip that are much less than the wavelength at the clock frequency. These short connections eliminate errors related to signal delays and phase changes.

With the RF system of the present invention, the RF excitation pulses used in conventional two-dimensional MRI methods can be programmed to achieve inter-slice phase coherency that is usually lost because of frequency offsets from the central Larmor frequency. The benefit of this technology becomes more advantageous with increases in the magnetic field of whole-body MRI scanners, where phase images can carry more information than amplitude images. With phase alignment between all two-dimensional slices, consistent phase analysis in three dimensions can be carried out without the need for additional (and rather long) three-dimensional acquisitions. Moreover, in the realm of echo-planar imaging, especially at high resolution, phase contrast in an arbitrary oblique plane can be obtained by postprocessing the full set of phase coherent slices.

The inter-slice coherence, which is set by adjusting the position of the RF pulse in relation to the slice selection gradient, is robust and valid not only for volumetric phase contrast imaging, but also for other sequences. For instance, the phase difference between slices in multiband excitation depends on this coherence as well. After initial positioning of the RF pulse, further adjustment is not necessary.

The present invention thus provides a solution to a previously unidentified problem in multiband excitation profiles, namely, the occurrence of so-called ghost slices. The solution to this problem includes using a system clock for pulse formation that is at the Larmor frequency. As a consequence, all RF pulses can be said to be “phase coherent.”

It follows that phase reference signals are no longer required in detection. It also follows that complex-valued functional connectivity studies across the full brain at high resolution are possible.

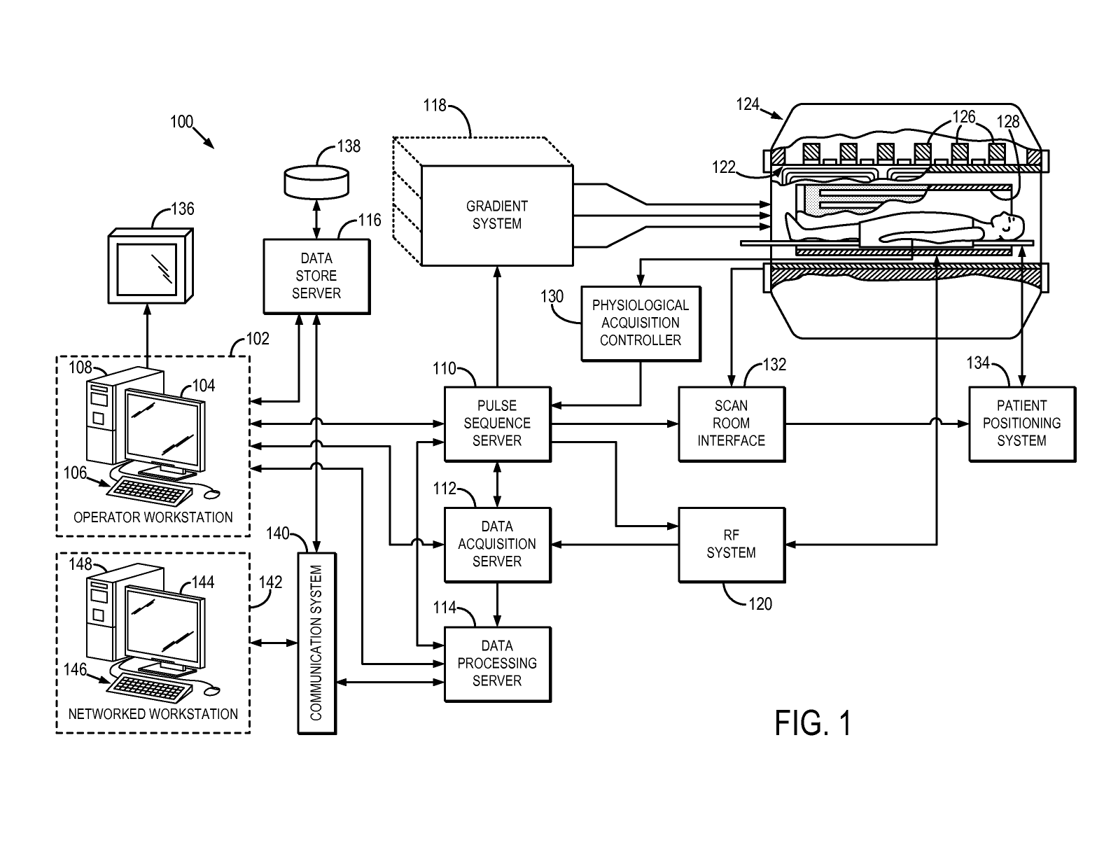

Referring particularly now to FIG. 1, an example of a magnetic resonance imaging (“MRI”) system 100 is illustrated. The MRI system 100 includes a workstation 102 having a display 104 and a keyboard 106. The workstation 102 includes a processor 108, such as a commercially available programmable machine running a commercially available operating system. The workstation 102 provides the operator interface that enables scan prescriptions to be entered into the MRI system 100. The workstation 102 is coupled to four servers: a pulse sequence server 110; a data acquisition server 112; a data processing server 114; and a data store server 116. The workstation 102 and each server 110, 112, 114, and 116 are connected to communicate with each other.

The pulse sequence server 110 functions in response to instructions downloaded from the workstation 102 to operate a gradient system 118 and a radiofrequency (“RF”) system 120. Gradient waveforms necessary to perform the prescribed scan are produced and applied to the gradient system 118, which excites gradient coils in an assembly 122 to produce the magnetic field gradients Gₓ, G_{y}, and G_{z} used for position encoding MR signals. The gradient coil assembly 122 forms part of a magnet assembly 124 that includes a polarizing magnet 126 and a whole-body RF coil 128.

RF excitation waveforms are applied to the RF coil 128, or a separate local coil (not shown in FIG. 1), by the RF system 120 to perform the prescribed magnetic resonance pulse sequence. Responsive MR signals detected by the RF coil 128, or a separate local coil (not shown in FIG. 1), are received by the RF system 120, amplified, demodulated, filtered, and digitized under direction of commands produced by the pulse sequence server 110. The RF system 120 includes an RF transmitter for producing a wide variety of RF pulses used in MR pulse sequences. The RF transmitter is responsive to the scan prescription and direction from the pulse sequence server 110 to produce RF pulses of the desired frequency, phase, and pulse amplitude waveform. The generated RF pulses may be applied to the whole body RF coil 128 or to one or more local coils or coil arrays (not shown in FIG. 1).

The RF system 120 also includes one or more RF receiver channels. Each RF receiver channel includes an RF preamplifier that amplifies the MR signal received by the coil 128 to which it is connected, and a detector that detects and digitizes the I and Q quadrature components of the received MR signal. The magnitude of the received MR signal may thus be determined at any sampled point by the square root of the sum of the squares of the I and Q components:

M=√I²+Q²

and the phase of the received MR signal may also be determined:

$$ϕ = {tan}^{- 1} ( \frac{Q}{I} ) . \qquad ( 2 )$$

The pulse sequence server 110 also optionally receives patient data from a physiological acquisition controller 130. The controller 130 receives signals from a number of different sensors connected to the patient, such as electrocardiograph (“ECG”) signals from electrodes, or respiratory signals from a bellows or other respiratory monitoring device. Such signals are typically used by the pulse sequence server 110 to synchronize, or “gate,” the performance of the scan with the subject's heart beat or respiration.

The pulse sequence server 110 also connects to a scan room interface circuit 132 that receives signals from various sensors associated with the condition of the patient and the magnet system. It is also through the scan room interface circuit 132 that a patient positioning system 134 receives commands to move the patient to desired positions during the scan.

The digitized MR signal samples produced by the RF system 120 are received by the data acquisition server 112. The data acquisition server 112 operates in response to instructions downloaded from the workstation 102 to receive the real-time MR data and provide buffer storage, such that no data is lost by data overrun. In some scans, the data acquisition server 112 does little more than pass the acquired MR data to the data processor server 114. However, in scans that require information derived from acquired MR data to control the further performance of the scan, the data acquisition server 112 is programmed to produce such information and convey it to the pulse sequence server 110. For example, during prescans, MR data is acquired and used to calibrate the pulse sequence performed by the pulse sequence server 110. Also, navigator signals may be acquired during a scan and used to adjust the operating parameters of the RF system 120 or the gradient system 118, or to control the view order in which k-space is sampled. In all these examples, the data acquisition server 112 acquires MR data and processes it in real-time to produce information that is used to control the scan.

The data processing server 114 receives MR data from the data acquisition server 112 and processes it in accordance with instructions downloaded from the workstation 102. Such processing may include, for example: Fourier transformation of raw k-space MR data to produce two or three-dimensional images; the application of filters to a reconstructed image; the performance of a backprojection image reconstruction of acquired MR data; the generation of functional MR images; and the calculation of motion or flow images.

Images reconstructed by the data processing server 114 are conveyed back to the workstation 102 where they are stored. Real-time images are stored in a data base memory cache (not shown in FIG. 1), from which they may be output to operator display 112 or a display 136 that is located near the magnet assembly 124 for use by attending physicians. Batch mode images or selected real time images are stored in a host database on disc storage 138. When such images have been reconstructed and transferred to storage, the data processing server 114 notifies the data store server 116 on the workstation 102. The workstation 102 may be used by an operator to archive the images, produce films, or send the images via a network to other facilities.

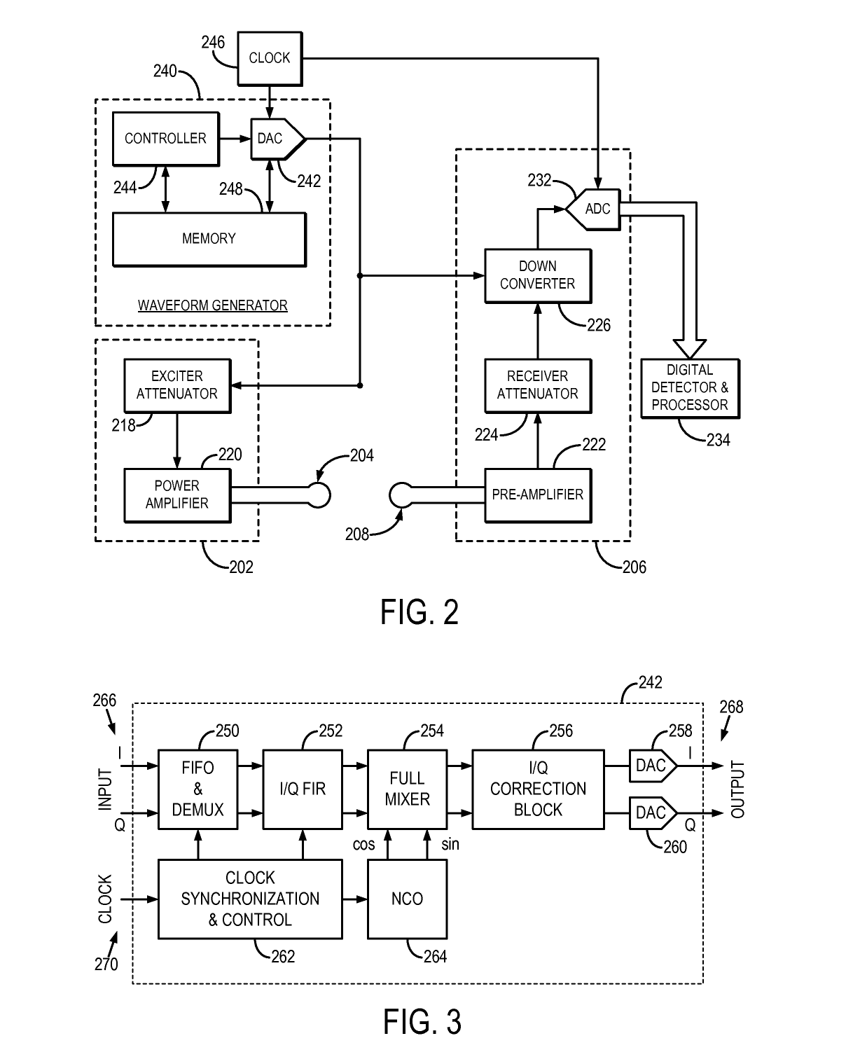

As shown in FIG. 1, the radio frequency (“RF”) system 120 may be connected to the whole body RF coil 128, or, as shown in FIG. 2, one or more transmission channels 202 of the RF system 120 may connect to an RF transmission coil 204 or an array thereof, and one or more receiver channels 206 may connect to a separate RF receiver coil 208 or an array thereof. Often, the transmission channel 202 is connected to the whole body RF coil 128 and each receiver section is connected to a separate local RF coil.

Referring particularly to FIG. 2, the RF system 120 includes at least one transmission channel 202 that produces a prescribed RF excitation field. In some configurations, the RF system 120 can include multiple transmission channels 202. In the latter configuration, the multiple transmission channels 202 can each be independently controlled, as described below.

Transmit pulses are formed in a waveform generator 240. The waveform generator 240 generally includes a digital-to-analog convertor (“DAC”) 242 and is controlled by a controller 244, such as a field-programmable gate array (“FPGA”). By way of example, the waveform generator 240 can be a Pentek Waveform Playback PCIe card, model 78621 (Upper Saddle River, N.J.), the DAC 242 can be a Texas Instrument DAC5688 chip or Texas Instrument DAC34SH84 chip, and the controller 244 can be a Virtex-6 FPGA, model LX240T or SX315T.

The DAC 242 in the waveform generator is driven by a high rate clock 246 to generate the Larmor frequency for the RF pulses. Recent technology developments allow the generation of Larmor frequencies upwards of 600 MHz when running at a 1.5 GHz clock speed. This clock speed is thus sufficient for MRI applications at magnetic field strengths up to 14 T.

The DAC 242 used in the RF transmitter 202 is selected to have connections that are shorter than the wavelength of a high rate clock signal generated by the clock 246. For instance, the clock signal can be at a rate of about 500 MHz to about 1.5 GHz. As such, the phase stability of the DAC 242 is sufficiently high so as to not require using a phase reference signal in the RF receiver 206.

The DAC 242 is operated in an interpolate mode to create RF pulses with a sampling time that, in one example, can be two nanoseconds. The RF pulses created in this manner also have smooth, stair-step-less modulation of the I and Q channels at a 16-bit resolution. This improves the spectral quality of the RF pulses created with the RF transmitter 202.

By way of example, RF pulses can be created by the waveform generator 240 with 128 nanosecond steps and can be synchronously upsampled in two stages. For instance, 8-fold upsampling can be carried out by an interpolator on the controller 244 and then sent to the DAC 242 for another 8- fold upsampling in an I/Q FIR block.

The complex modulated waveforms generated in the waveform generator 240 can be output by the DAC 242 and stored in internal memory 248 of the waveform generator 240, which permits fast transfer of data to the RF transmitter 202.

The waveform generator 240 generates a base, or carrier, frequency of the RF pulses in response to a set of digital signals from the pulse sequence server 110. These digital signals indicate the frequency and phase of the RF carrier signal to be produced by the waveform generator 240. The RF carrier is applied to a modulator and up converter in the controller 244 where its amplitude is modulated in response to a signal also received from the pulse sequence server 110. The signal defines the envelope of the RF pulse to be produced and is produced by sequentially reading out a series of stored digital values. These stored digital values may be changed to enable any desired RF pulse envelope to be produced.

The magnitude of the RF excitation pulse produced by the waveform generator 240 is attenuated by an exciter attenuator circuit 218 that receives a digital command from the pulse sequence server 110. The attenuated RF excitation pulses are then applied to a power amplifier 220 that drives the RF transmission coil 204.

The MR signal produced by the subject is picked up by the RF receiver coil 208 and applied through a preamplifier 222 to the input of a receiver attenuator 224. The receiver attenuator 224 further amplifies the signal by an amount determined by a digital attenuation signal received from the pulse sequence server 110. The received signal is at or around the Larmor frequency, and this high frequency signal is down converted in a two step process by a down converter 226. The down converter 226 first mixes the MR signal with the carrier signal received from the waveform generator 240. The down converted MR signal is applied to the input of an analog-to-digital converter ADC 232 that samples and digitizes the analog signal. As an alternative to down conversion of the high frequency signal, the received analog signal can also be detected directly with an appropriately fast ADC and/or with appropriate undersampling. The sampled and digitized signal is then applied to a digital detector and signal processor 234 that produces in-phase (I) and quadrature (Q) values corresponding to the received signal. The resulting stream of digitized I and Q values of the received signal are output to the data acquisition server 112. The clock 246 also generates a sampling signal that is applied to the ADC 232. By way of example, ADC 232 may be a Mercury ECDR-GC316-PMC.

Optionally, the clock 246 can be a 10 MHz reference clock of the MRI scanner. In this instance, a 100-MHz acquisition clock applied to the ADC 232 can be derived from the 10-MHz reference clock in a phase-locked loop. This clock 10 MHz clock signal can be sent to the waveform generator 240 to synchronize an internal clock on the DAC 242, such as an internal 500 MHz clock.

An example of a DAC 242 that can be used in the waveform generator 2440 is illustrated in FIG. 3. This DAC 242 is an interpolating dual-channel DAC. The DAC 242 generally includes an input FIFO and demultiplexer 250; an interpolator, such as an I/Q finite impulse response (“FIR”) interpolator 252; a full mixer 254; and I/Q correction block 256; a DAC 258 for the in-phase channel; a DAC 260 for the quadrature channel; a clock synchronization and control block 262; and a numerically controlled oscillator (“NCO”) 264. Digital signals received from the pulse sequencer 110 are provided to the DAC 242 at 266, and the complex waveforms are output at 268.

The Larmor frequency is generated by supplying the clock signal 270 from the clock 246 to the NCO 264 via the clock synchronization and control block 262 By way of example, the interpolator 252 can be used at a maximum up-conversion rate to reduce the input data clock down to well below the limit of the FPGA controller 244.

This process of digital convolution is equivalent to making a Fourier transform of the pulse, filling zeroes on the left and right parts of the spectrum thus increasing frequency range by 64 times, and making an inverse Fourier transform. The final modulation, at 500 MHz, is made by the full mixer 254.

Tailored pulses for multiband acquisitions can be formed by the inverse Fourier transform of the required slice profiles, including not only positions computed against the Larmor frequency, but also relative phases. The pulse data in the form of I and Q 16-bit arrays can be multiplied by a Hamming window to reduce truncation artifacts. RF pulses can be selected to have a pulse duration time of 6.4 ms with a final 2-ns update time. This pulse duration is twice that of the default mode of normal MRI scanners, which reduces the peak power required for multiband excitation so that a 4-fold acceleration can be achieved at a ninety degree flip angle.

Each complex-valued composite RF pulse was formed from a single transmit frequency. With this method, reference slices needed for multislice separation can be acquired with exactly the same phase as the combined image by masking the unneeded part of the composite profile. For four slices, a thirty degree phase difference between each slice is a reasonable choice.

The present invention has been described in terms of one or more preferred embodiments, and it should be appreciated that many equivalents, alternatives, variations, and modifications, aside from those expressly stated, are possible and within the scope of the invention.

1. A radio frequency (RF) system for a magnetic resonance imaging (“MRI”) system, comprising:
a clock configured to generate a clock signal;
an RF transmitter in communication with the clock, comprising:
an oscillator capable of receiving the clock signal from the clock and generating a Larmor frequency signal in response thereto;
a digital-to-analog convertor capable of receiving the Larmor frequency signal from the oscillator and using the Larmor frequency signal to generate a complex waveform that defines an RF pulse;
an RF receiver in communication with the RF transmitter, comprising:
an analog-to-digital converter capable of receiving a magnetic resonance signal produced by a subject placed in the MRI system and configured to produce a complex digital signal therefrom; and
a demodulator connected to receive the Larmor Frequency signal from the RF transmitter and the complex digital signal from the analong-to-digital convertor, the demodulator being capable of demodulating the complex digital signal using the Larmor frequency.

2. The RF system as recited in claim 1 in which the digital-to-analog convertor includes electrical connections that are shorter than a wavelength of the clock signal.

3. The RF system as recited in claim 2 in which the clock signal is about 500 MHz to about 1.5 GHz.

4. The RF system as recited in claim 1 in which the analog-to-digital converter includes at least one of a single-channel receiver chip and multi-channel receiver chip capable of digitizing the magnetic resonance signal.

5. The RF system as recited in claim 1 in which the RF transmitter comprises a plurality of digital-to-analog converters each capable of producing a complex RF waveform.

6. The RF system as recited in claim 5 in which each of the plurality of digital-to-analog convertors correspond to an independently controllable transmit channel.

7. The RF system as recited in claim 1 in which the oscillator is a numerically controlled oscillator.

8. A waveform generator capable of generating complex waveforms that define radio frequency (RF) pulses for use in a magnetic resonance imaging (MRI) system, comprising:
a digital-to-analog convertor assembly comprising:
an input capable of receiving digital signals that define a complex waveform to be generated;
an oscillator capable of generating a Larmor frequency in response to a clock signal received from a clock;
a mixer in communication with the input and the oscillator, the mixer configured to generate a mixed signal by mixing the digital signals and the Larmor frequency;
a digital-to-analog convertor capable of converting the mixed signal into a complex waveform;
an output capable of outputting the complex waveform to an RF transmitter; and
a controller in communication with the digital-to-analog convertor assembly and configured to control operation of the digital-to-analog convertor.

9. The waveform generator as recited in claim 8 further comprising an internal clock in communication with the digital-to-analog convertor and configured to provide the clock signal to the oscillator.

10. The waveform generator as recited in claim 9 in which the internal clock is configured to generate a clock signal having a frequency that is about 500 MHz to about 1.5 GHz.

11. The waveform generator as recited in claim 8 in which the digital-to-analog convertor assembly is constructed to have electrical connections that are shorter than a wavelength of the clock signal received by the oscillator.
